(19) United States
(12) Patent Application Publication
(10) Pub. No.: US 2012/0056270 A1
(43) Pub. Date: Mar. 8, 2012

(54) SEMICONDUCTOR DEVICE AND METHOD FOR FABRICATING THE SAME

(75) Inventors: Tomohiro FUJITA, Toyama (JP); Junji HIRASE, Toyama (JP); Yoshihiro SATO, Toyama (JP)

(73) Assignee: PANASONIC CORPORATION, Osaka (JP)

(21) Appl. No.: 13/294,727

(22) Filed: Nov. 11, 2011

Related U.S. Application Data
(63) Continuation of application No. PCT/JP2010/001143, filed on Feb. 22, 2010.

(30) Foreign Application Priority Data
Jul. 17, 2009 (JP) 2009-168592

(51) Int. Cl. H01L 27/092

(52) U.S. Cl. 257/369; 257/E27.062

(57) ABSTRACT

A semiconductor device includes an NMIS transistor including a first gate insulating film containing a high-k dielectric and a first gate electrode provided on the first gate insulating film and containing a metal material and a PMIS transistor including a second gate insulating film containing a high-k dielectric and a second gate electrode provided on the second gate insulating film and containing a metal material. A side surface of the first gate insulating film is located at an inner side of a side surface of the first gate electrode. A ratio of a length of the first gate insulating film along a gate length direction to a length of the first gate electrode along the gate length direction is lower than a ratio of a length of the second gate insulating film along the gate length direction to a length of the second gate electrode along the gate length direction.

### CROSS-REFERENCE TO RELATED APPLICATION

This is a continuation of PCT International Application No. PCT/JP2010/001143 filed on Feb. 22, 2010, which claims priority to Japanese Patent Application No. 2009-168592 filed on Jul. 17, 2009. The disclosures of these applications including the specifications, the drawings, and the claims are hereby incorporated by reference in their entirety.

### BACKGROUND

The present disclosure relates to semiconductor devices and methods for fabricating the semiconductor devices, and more particularly to a semiconductor device including a field effect transistor having a gate insulating film including a high-dielectric-constant film (hereinafter referred to as a high-k film), and a method for fabricating the semiconductor device.

With recent increases in integration degree and speed of large scale integrated (LSI) circuits, metal insulator semiconductor (MIS) transistors, which are fundamental elements of the circuits, have been miniaturized according to scaling rules. The scaling rules enable enhanced electrical characteristics of transistors through simultaneous miniaturization of dimensions such as the gate length of gate electrodes and the thickness of gate insulating films in the MIS transistors.

In view of this, a technique using a high-k film instead of a conventional silicon oxynitride film as a material capable of reducing leakage current as well as reducing the equivalent oxide thickness (EOT) of a gate insulating film has been proposed in recent years. In the case of using a high-k film in a gate insulating film, a gate electrode using a conventional polycrystalline silicon film cannot obtain a desired work function, and the threshold voltage of a transistor cannot be sufficiently reduced. For this reason, a technique using a metal material such as titanium nitride and tantalum nitride for a gate electrode or a material containing lanthanum or aluminium for a gate insulating film is proposed.

A high-k dielectric herein is a material having a relative dielectric constant of about 8 and higher than that of Si₃N₄. Examples of high-k dielectrics include hafnium oxide (HfO₂), zirconium oxide (ZrO₂), and aluminium oxide (Al₂O₃). If such a high-k dielectric is used in a gate insulating film, negative fixed charge generated during fabrication processes is easily trapped in a part of the gate insulating film located immediately under an end of a gate electrode, causing the threshold voltage of an NMIS transistor to increase. This increase in the threshold voltage causes a substantial decrease in a positive voltage applied to the gate electrode, resulting in the problem of a decrease in driving current.

Examples of fabrication processes in which negative fixed charge is generated include the process of forming an offset spacer after processing of a gate electrode. In T. Watanabe et. al, “Impact of Hf concentration on performance and reliability for HfSiON-CMOSFET,” IEDM 2004, p. 507, a material for an offset spacer is changed from a conventional silicon oxide film which easily generates negative fixed charge to a silicon nitride film which does not easily generate negative fixed charge, thereby enabling reduction of an increase in the threshold voltage of an NMIS transistor.

### SUMMARY

In the case of reducing an introduction of negative fixed charge into a gate insulating film using a silicon nitride film for an offset spacer, however, there arises a problem in which the threshold voltage of a PMIS transistor increases and, thereby, driving current decreases.

In an aspect of the present disclosure, a semiconductor device in which a high-k dielectric is used in a gate insulating film can eliminate the conventional problem described above, and can reduce the threshold voltages of both an NMIS transistor and a PMIS transistor.

To achieve the object described above, a semiconductor device in an aspect of the present disclosure includes: a substrate including a first active region and a second active region; an NMIS transistor provided on the first active region; and a PMIS transistor provided on the second active region, wherein the NMIS transistor includes a first gate insulating film provided on the first active region and containing a high-k dielectric and a first gate electrode provided on the first gate insulating film and containing a metal material, the PMIS transistor includes a second gate insulating film provided on the second active region and containing a high-k dielectric and a second gate electrode provided on the second gate insulating film and containing a metal material, a side surface of the first gate insulating film is located at an inner side of a side surface of the first gate electrode, and a ratio of a length of the first gate insulating film along a gate length direction to a length of the first gate electrode along the gate length direction is lower than a ratio of a length of the second gate insulating film along the gate length direction to a length of the second gate electrode along the gate length direction.

With this structure, in the first gate insulating film of the NMIS transistor, part of the first gate insulating film doped with negative fixed charge in a fabrication process step (i.e., an end of the first gate insulating film in the fabrication process step) is removed. Thus, an increase in the threshold voltage of the NMIS transistor can be reduced. In addition, in the second gate insulating film of the PMIS transistor, negative fixed charge can be intentionally introduced in a fabrication process step. Thus, an increase in the threshold voltage of the PMIS transistor can also be reduced.

Further, a material having a dielectric constant lower than that of the first gate insulating film formed under the end of the first gate electrode can reduce the parasitic capacitance.

A side surface of the second gate insulating film may be flush with a side surface of the second gate electrode. Alternatively, a side surface of the second gate insulating film may be located at an inner side of a side surface of the second gate electrode. An end of the second gate insulating film may project from a side surface of the second gate electrode.

A method for fabricating a semiconductor device in an aspect of the present disclosure includes the steps of: (a) forming a first gate insulating film including a high-k dielectric and a first gate electrode including a metal material on a first active region formed in a substrate and forming a second gate insulating film including a high-k dielectric and a second gate electrode including a metal material on a second active region formed in the substrate; (b) introducing negative fixed charge into an end of the first gate insulating film and an end of the second gate insulating film; and (c) removing the end of the first gate insulating film after step (b). Step (b) is preferably performed at the same time as, or after, step (a).

With this method, the negative fixed charge introduced into the second gate insulating film in step (b) can reduce the threshold voltage of the PMIS transistor, and removal of a part of the first gate insulating film doped with the negative fixed charge in step (c) can effectively reduce the threshold voltage of the NMIS transistor.

Further, a first offset spacer of a silicon nitride film may be formed on a side surface of the first gate electrode and a second offset spacer of a silicon nitride film may be formed on a side surface of the second gate electrode, after step (c). In this case, introduction of the negative fixed charge into the first gate insulating film during formation of the offset spacers can be reduced.

As described above, with the method for forming an example semiconductor device of the present disclosure, introduction of negative fixed charge into the insulating film of the NMIS transistor can be reduced, whereas introduction of negative fixed charge into the insulating film of the PMIS transistor is promoted. As a result, the threshold voltages of both of the NMIS transistor and the PMIS transistor can be reduced.

### BRIEF DESCRIPTION OF THE DRAWINGS

FIGS. 1A-1E are cross-sectional views showing a method for fabricating a semiconductor device according to a first embodiment.

FIGS. 2A-2D are cross-sectional views showing the method for fabricating a semiconductor device of the first embodiment.

FIG. 3A is a cross-sectional view showing a method for fabricating a semiconductor device according to a first variation of the first embodiment. FIG. 3B is a cross-sectional view showing a method for fabricating a semiconductor device according to a second variation of the first embodiment.

FIGS. 4A-4D are cross-sectional views showing a method for fabricating a semiconductor device according to a second embodiment.

FIGS. 5A-5C are cross-sectional views showing a method for fabricating a semiconductor device of the second embodiment.

### DETAILED DESCRIPTION

### First Embodiment

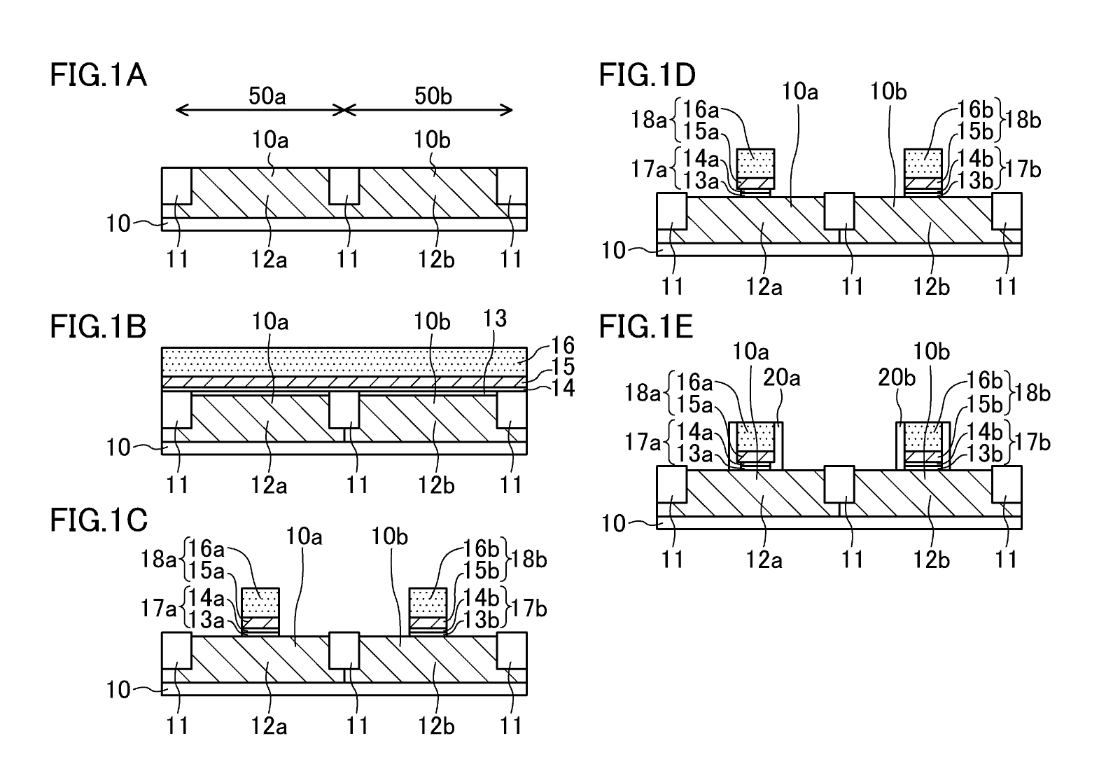

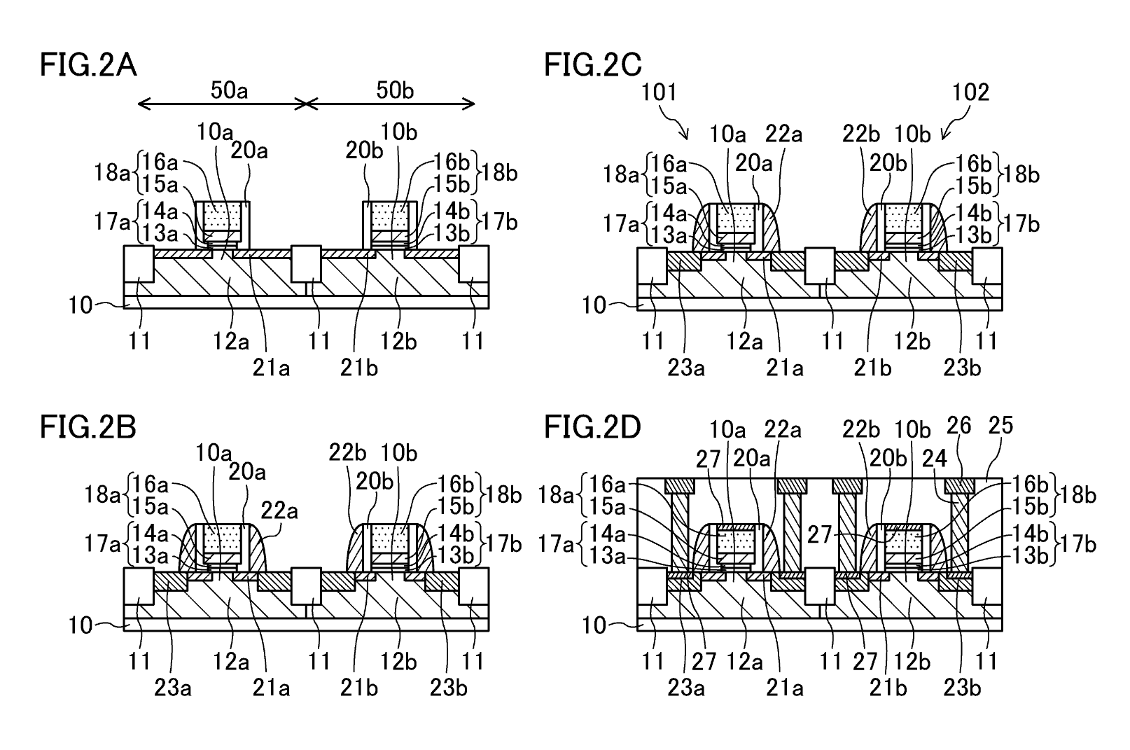

A method for fabricating a semiconductor device according to a first embodiment of the present disclosure will be described hereinafter with reference to the drawings. FIGS. 1A-1E and FIGS. 2A-2D are cross-sectional views showing a method for fabricating a semiconductor device according to the first embodiment.

First, as illustrated in FIG. 1A, a p-type region 12a is formed in an NMIS region 50a of a semiconductor substrate 10 of silicon, and an n-type region 12b is formed in a PMIS region 50b of the semiconductor substrate 10. Then, an isolation region 11 of, for example, shallow trench isolation (STI) is formed in the semiconductor substrate 10, thereby defining a first active region 10a surrounded by the isolation region 11 in the p-type region 12a and a second active region 10b surrounded by the isolation region 11 in the n-type region 12b. The first active region 10a is doped with a p-type impurity such as boron, and the second active region 10b is doped with an n-type impurity such as phosphorus.

Next, as illustrated in FIG. 1B, the semiconductor substrate 10 is oxidized by thermal treatment in an oxidizing atmosphere at about 1000° C., for example, thereby forming a first dielectric film 13 of silicon oxide having a thickness of 1 nm on the semiconductor substrate 10. Subsequently, a second dielectric film 14 of a material, such as HfSiON, containing nitrogen, oxygen, hafnium, and silicon is deposited by chemical vapor deposition (CVD) on the first dielectric film 13 to a thickness of about 2 nm. The second dielectric film 14 is a high-k film. Thereafter, a first gate electrode film 15 of titanium nitride is deposited by CVD on the second dielectric film 14 to a thickness of about 20 nm. Subsequently, a second gate electrode film 16 of polysilicon is deposited by CVD on the first gate electrode film 15 to a thickness of about 80 nm.

Then, as illustrated in FIG. 1C, a resist material is applied onto the second gate electrode film 16, and a resist pattern is formed by lithography. With this resist pattern, anisotropic dry etching is performed on the first gate electrode film 15, the second gate electrode film 16, the first dielectric film 13, and the second dielectric film 14.

In the manner described above, in the NMIS region 50a, a first gate insulating film 17a including a first lower gate insulating film 13 a as a part of the first dielectric film 13 and a first upper gate insulating film 14a as a part of the second dielectric film 14, and a first gate electrode 18a including a first lower gate electrode 15a as a part of the first gate electrode film 15 and a first upper gate electrode 16a as a part of the second gate electrode film 16, are formed. In the PMIS region 50b, a second gate insulating film 17b including a second lower gate insulating film 13b as a part of the first dielectric film 13 and a second upper gate insulating film 14b as a part of the second dielectric film 14, and a second gate electrode 18b including a second lower gate electrode 15b as a part of the first gate electrode film 15 and a second upper gate electrode 16b as a part of the second gate electrode film 16, are formed.

Subsequently, the resist material is removed by ashing. In this process step, an etching gas containing oxygen is used in dry etching or ashing. This etching gas slightly oxidizes parts of the first gate insulating film 17a located immediately under ends of the first gate electrode 18a (i.e., ends of the first gate insulating film 17a) and parts of the second gate insulating film 17b located immediately under ends of the second gate electrode 18b (i.e., ends of the second gate insulating film 17b), thereby introducing negative fixed charge into a region extending to a distance of about 1 nm to about 2 nm from each side surface of the first gate insulating film 17a and the second gate insulating film 17b. In the case of performing dry etching using an etching gas containing oxygen, negative fixed charge is introduced into ends of the first gate insulating film 17a and ends of the second gate insulating film 17b simultaneously with formation of the first gate electrode 18a, the first gate insulating film 17a, the second gate electrode 18b, and the second gate insulating film 17b.

Thereafter, as illustrated in FIG. 1D, a resist material is applied onto the semiconductor substrate 10, and then part of the resist material located on the first active region 10a is removed by lithography. Then, part of the first gate insulating film 17a is selectively wet etched using an aqueous solution containing hydrogen fluoride with the second active region 10b covered with the resist material. In this manner, parts of the first gate insulating film 17a into which the fixed charge has been introduced are removed, resulting in that the ends of the first gate insulating film 17a are located at an inner side of the side surface of the first gate electrode 18a when viewed from above. To effectively remove the fixed charge, it is preferable to remove parts of the first gate insulating film 17a each extending to a distance of about 1 nm to about 2 nm from the original side surface thereof. Subsequently, the resist material is removed by ashing using a nitrogen gas. The ashing using a nitrogen gas can prevent the fixed charge from being introduced into the first gate insulating film 17a again.

Then, as illustrated in FIG. 1E, a silicon nitride film is deposited by CVD on the semiconductor substrate 10 to a thickness of about 8 nm, and then is subjected to dry etching, thereby forming a first offset spacer 20a on each side surface of the first gate electrode 18a, and a second offset spacer 20b on each side surface of the second gate electrode 18b. At this time, the first offset spacer 20a is also formed on each side surface of the first gate insulating film 17a. Accordingly, the first offset spacer 20a is formed under the ends of the first gate electrode 18a, whereas the second offset spacer 20b is not formed under any of the ends of the second gate electrode 18b.

Subsequently, as illustrated in FIG. 2A, through lithography and ion implantation, arsenic is implanted in the first active region 10a with an implantation energy of, for example, 2 keV at an implantation dose of 1×10¹⁵/cm² with the first gate electrode 18a used as a mask, thereby forming an n-type first extension region 21a in a part of the first active region 10a at each side of the first gate electrode 18a. On the other hand, boron is implanted in the second active region 10b with an implantation energy of, for example, 2 keV at an implantation dose of 1×10¹⁵/cm² with the second gate electrode 18b used as a mask, thereby forming a p-type second extension region 21b in parts of the second active region 10b at the sides of the second gate electrode 18b.

Thereafter, as illustrated in FIG. 2B, with a known method, a first sidewall spacer 22a is formed on each side surface of the first gate electrode 18a with the first offset spacer 20a interposed therebetween. Then, using the first gate electrode 18a and the first sidewall spacer 22a as masks, ion implantation of an n-type impurity is performed, thereby forming n-type first source/drain regions 23a in parts of the first active region 10a at both sides of the first gate electrode 18a. On the other hand, a second sidewall spacer 22b is formed on each side surface of the second gate electrode 18b with the second offset spacer 20b interposed therebetween. Then, using the second gate electrode 18b and the second sidewall spacer 22b as masks, ion implantation of a p-type impurity is performed, thereby forming p-type second source/drain regions 23b in parts of the second active region 10b at both sides of the second gate electrode 18b.

Then, as illustrated in FIG. 2C, thermal treatment at about 1050° C. is performed such that impurities implanted in the extension regions and the source/drain regions are diffused, thereby forming an n-channel MIS transistor (a NMIS transistor) 101 and a p-channel MIS transistor (a PMIS transistor) 102. At this time, an the end of the first extension region 21a coincides with the end of the first gate insulating film 17a (i.e., the boundary between the first gate insulating film 17a and the first offset spacer 20a) or is at a position situated nearer the middle of the first gate electrode 18a in relation to the end of the first gate insulating film 17a (such that the first extension region 21a overlaps the end of the first gate insulating film 17a) when viewed from above.

Thereafter, as illustrated in FIG. 2D, with a known method, a silicide layer 27 containing a silicide material such as nickel is formed on the first gate electrode 18a, the second gate electrode 18b, the first source/drain regions 23a, and the second source/drain regions 23b, and then an interlayer insulating film 25, a contact 24, and an interconnect 26 are formed in this order.

A semiconductor device of this embodiment formed in the foregoing manner includes the NMIS transistor 101 and the PMIS transistor 102.

The NMIS transistor 101 is provided on the first active region 10a, and includes: the first gate insulating film 17a containing a high-k dielectric; the first gate electrode 18a provided on the first gate insulating film 17a and containing a metal material such as titanium nitride; the first offset spacers 20a provided on the side surfaces of the first gate electrode 18a and the first gate insulating film 17a; the first sidewall spacers 22a provided to the side surfaces of the first gate electrode 18a and the first gate insulating film 17a with the first offset spacers 20a interposed therebetween; and the first extension regions 21a and the first source/drain regions 23a formed in parts of the first active region 10a at both sides of the first gate electrode 18a. The side surfaces of the first gate insulating film 17a are located at inner sides of the respective side surfaces of the first gate electrode 18a when viewed from above.

The PMIS transistor 102 is provided on the second active region 10b, and includes: the second gate insulating film 17b containing a high-k dielectric; the second gate electrode 18b provided on the second gate insulating film 17b and containing a metal material such as titanium nitride; the second offset spacers 20b provided on the side surfaces of the second gate electrode 18b and the second gate insulating film 17b; the second sidewall spacers 22b provided to the side surfaces of the second gate electrode 18b and the second gate insulating film 17b with the second offset spacers 20b interposed therebetween; and the second extension regions 21b and the second source/drain regions 23b formed in parts of the second active region 10b at both sides of the second gate electrode 18b.

In the semiconductor device of this embodiment, the side surfaces of the first gate insulating film 17a are located at inner sides of the respective side surfaces of the first gate electrode 18a when viewed from above. In addition, the ratio of the width (i.e., the length along the gate length direction) of the first gate insulating film 17a to the width (i.e., the length along the gate length direction) of the first gate electrode 18a, i.e., (the width of the first gate insulating film 17a)/(the width of the first gate electrode 18a), is lower than the ratio of the width (i.e., the length along the gate length direction) of the second gate insulating film 17b to the width (i.e., the length along the gate length direction) of the second gate electrode 18b, i.e., (the width of the second gate insulating film 17b)/(the width of the second gate electrode 18b). Further, part of the second gate insulating film 17b located immediately under the end of the second gate electrode 18b (i.e., the end of the second gate insulating film 17b) is doped with a larger amount of negative fixed charge than the end of the first gate insulating film 17a. Each of the side surfaces of the second gate insulating film 17b is substantially flush with an associated one of the side surfaces of the second gate electrode 18b.

The structure in which the first offset spacers 20a of a material (e.g., silicon nitride) having a dielectric constant lower than that of the first gate insulating film 17a are formed under the ends of the first gate electrode 18a can reduce parasitic capacitance.

With the foregoing method of this embodiment, negative fixed charge is intentionally generated in the second gate insulating film 17b of the PMIS transistor 102 in the process step shown in FIG. 1C. Accordingly, the threshold voltage of the PMIS transistor 102 can be reduced.

Since part of the first gate insulating film 17a of the NMIS transistor 101 in which negative fixed charge has been generated is removed in the process step shown in FIG. 1D, an influence of the negative fixed charge is reduced, thereby reducing an increase in the threshold voltage of the NMIS transistor 101. As a result, a decrease in driving current can be reduced.

A high-k material contained in the first upper gate insulating film 14a and the second upper gate insulating film 14b may be other high-melting-point materials. The metal material contained in the first lower gate electrode 15a and the second lower gate electrode 15b is not limited to titanium nitride.

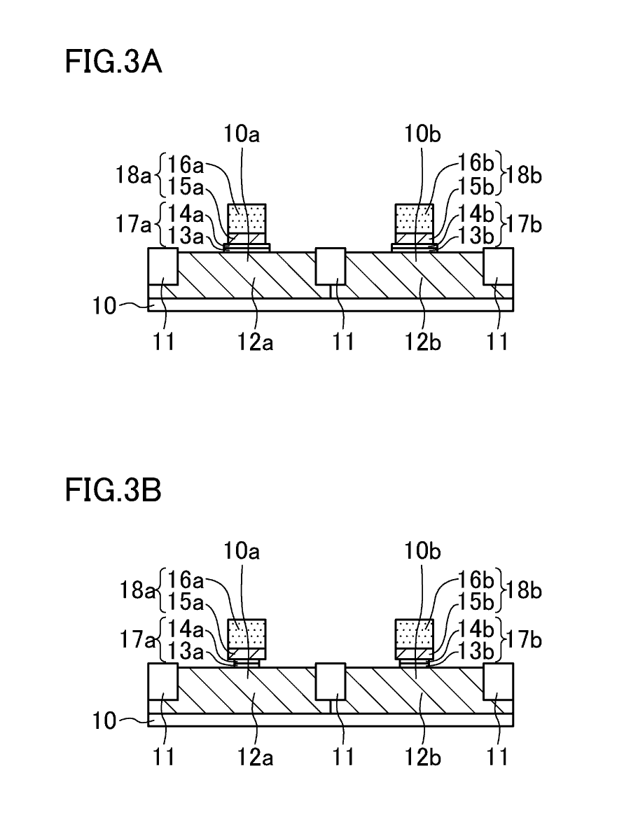

FIG. 3A is a cross-sectional view showing a method for fabricating a semiconductor device according to a first variation of this embodiment. FIG. 3B is a cross-sectional view showing a method for fabricating a semiconductor device according to a second variation of this embodiment.

As illustrated in FIG. 3A, dry etching for forming the first gate insulating film 17a, the second gate insulating film 17b, the first gate electrode 18a, and the second gate electrode 18b may be a combination of anisotropic dry etching and isotropic dry etching in the process step shown in FIG. 1C such that the ends of the first gate insulating film 17a project from the respective side surfaces of the first gate electrode 18a and the ends of the second gate insulating film 17b project from the respective side surfaces of the second gate electrode 18b. In this case, part of the first gate insulating film 17a where negative fixed charge has been generated can be effectively removed by selectively removing the ends of the first gate insulating film 17a through wet etching in a manner similar to the process step shown in FIG. 1D. The structure obtained with this method differs from the structure shown in FIG. 2D in that the ends of the second gate insulating film 17b project from the respective side surfaces of the second gate electrode 18b.

In addition, as illustrated in FIG. 3B, wet etching with ammonia-hydrogen peroxide mixture cleaning may be performed in order to facilitate removal of the resist material in ashing in the process step shown in FIG. 1D such that the first gate insulating film 17a is recessed from the side surfaces of the first gate electrode 18a and the second gate insulating film 17b is recessed from the side surfaces of the second gate electrode 18b. The structure obtained with this method differs from the structure shown in FIG. 2D in that the side surfaces of the second gate insulating film 17b are located at inner sides of the respective side surfaces of the second gate electrode 18b when viewed from above. In this case, however, the ratio of the width of the first gate insulating film 17a to the width of the first gate electrode 18a is also lower than the ratio of the width of the second gate insulating film 17b to the width of the second gate electrode 18b.

### Second Embodiment

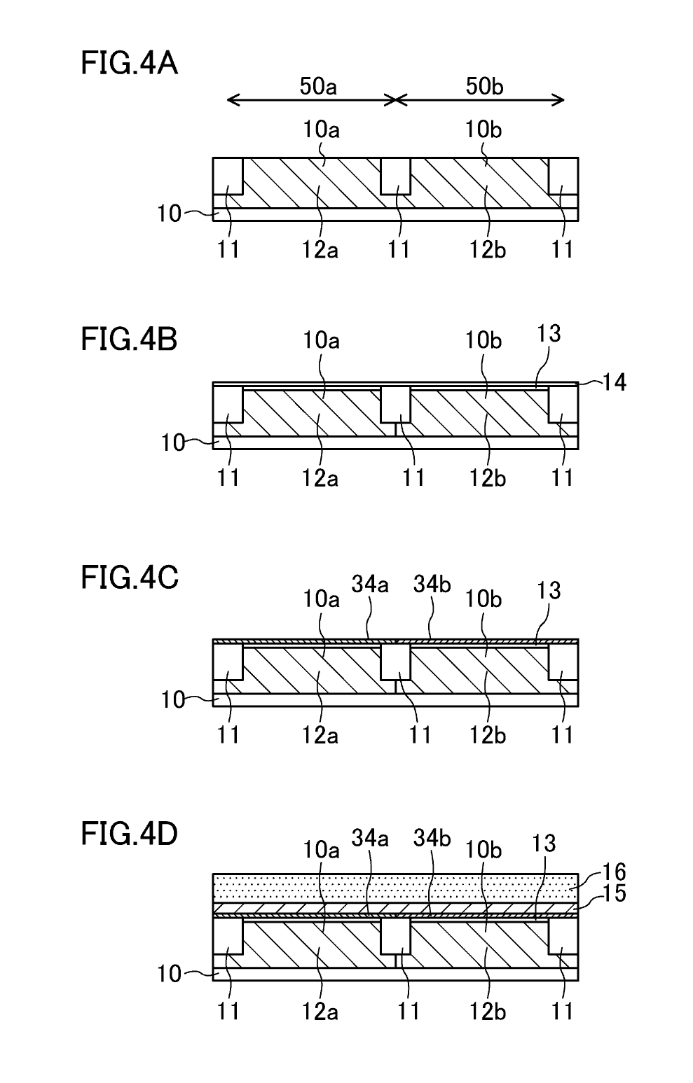

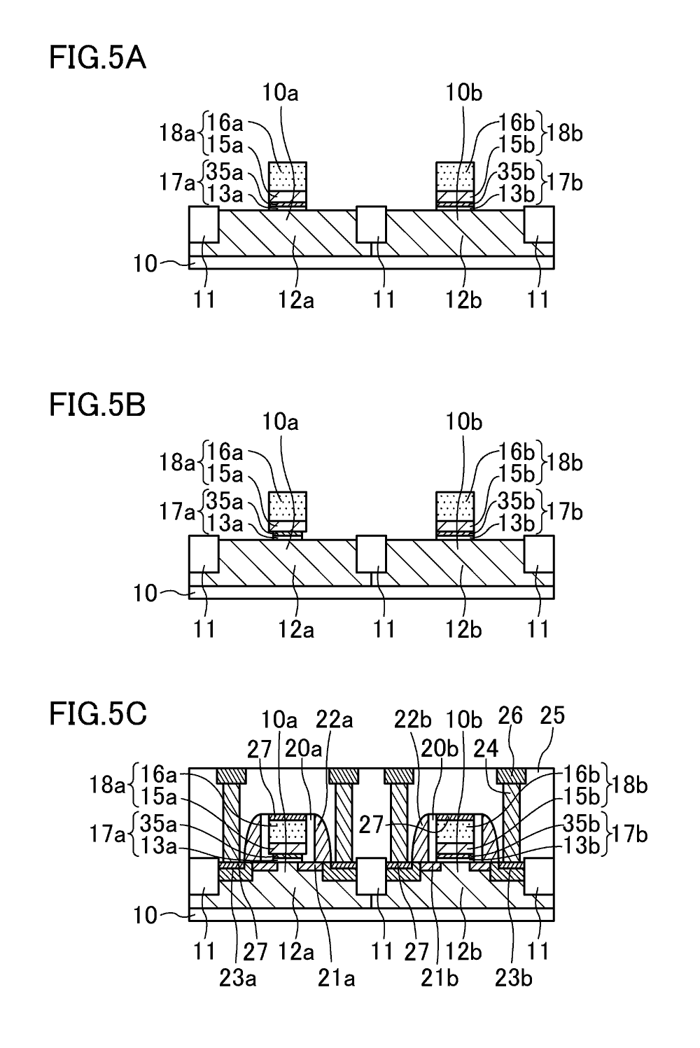

A method for fabricating a semiconductor device according to a second embodiment of the present disclosure will be described hereinafter with reference to the drawings. FIGS. 4A-4D and FIGS. 5A-5C are cross-sectional views showing a method for fabricating a semiconductor device according to the second embodiment.

First, as illustrated in FIG. 4A, a p-type region 12a is formed in an NMIS region 50a of a semiconductor substrate 10 of silicon, and an n-type region 12b is formed in a PMIS region 50b of the semiconductor substrate 10. Then, an isolation region 11 of, for example, shallow trench isolation (STI) is formed in the semiconductor substrate 10, thereby defining a first active region 10a surrounded by the isolation region 11 in the p-type region 12a and a second active region 10b surrounded by the isolation region 11 in the n-type region 12b. The first active region 10a is doped with a p-type impurity such as boron, and the second active region 10b is doped with an n-type impurity such as phosphorus.

Next, as illustrated in FIG. 4B, the semiconductor substrate 10 is oxidized by thermal treatment in an oxidizing atmosphere at about 1000° C., for example, thereby forming a first dielectric film 13 of silicon oxide having a thickness of 1 nm on the semiconductor substrate 10. Subsequently, a second dielectric film (a high-k film) 14 containing nitrogen, oxygen, hafnium, and silicon is deposited by CVD on the first dielectric film 13 to a thickness of about 2 nm.

Then, as illustrated in FIG. 4C, CVD, lithography, and wet etching are repeatedly performed, thereby forming lanthanum on the second dielectric film 14 above the first active region 10a and aluminium on the second dielectric film 14 above the second active region 10b. Then, thermal treatment is performed at about 700° C., thereby diffusing lanthanum and aluminium in the second dielectric film 14. Accordingly, a third dielectric film 34a containing lanthanum is formed above the first active region 10a, and a fourth dielectric film 34b containing aluminium is formed above the second active region 10b.

Thereafter, as illustrated in FIG. 4D, a first gate electrode film 15 of titanium nitride is deposited by CVD on the third dielectric film 34a and the fourth dielectric film 34b to a thickness of about 20 nm. Subsequently, a second gate electrode film 16 of polysilicon is deposited by CVD on the first gate electrode film 15 to a thickness of about 80 nm.

Subsequently, as illustrated in FIG. 5A, a resist material is applied onto the second gate electrode film 16, and a resist pattern is formed by lithography. With this resist pattern, anisotropic dry etching is performed on the first gate electrode film 15, the second gate electrode film 16, the first dielectric film 13, the third dielectric film 34a, and the fourth dielectric film 34b.

In the manner described above, in the NMIS region 50a, a first gate insulating film 17a including a first lower gate insulating film 13 a as a part of the first dielectric film 13 and a first upper gate insulating film 35a as a part of the third dielectric film 34a, and a first gate electrode 18a including a first lower gate electrode 15a as a part of the first gate electrode film 15 and a first upper gate electrode 16a as a part of the second gate electrode film 16, are formed. In the PMIS region 50b, a second gate insulating film 17b including a second lower gate insulating film 13b as a part of the first dielectric film 13 and a second upper gate insulating film 35b as a part of the fourth dielectric film 34b, and a second gate electrode 18b including a second lower gate electrode 15b as a part of the first gate electrode film 15 and a second upper gate electrode 16b as a part of the second gate electrode film 16, are formed.

Then, the resist material is removed by ashing. In this process step, an etching gas containing oxygen is used in dry etching or ashing. This etching gas slightly oxidizes parts of the first gate insulating film 17a located immediately under ends of the first gate electrode 18a (i.e., ends of the first gate insulating film 17a) and parts of the second gate insulating film 17b located immediately under ends of the second gate electrode 18b (i.e., ends of the second gate insulating film 17b), thereby introducing negative fixed charge into a region extending to a distance of about 1 nm to about 2 nm from each side surface of the first gate insulating film 17a and the second gate insulating film 17b.

Thereafter, as illustrated in FIG. 5B, the first gate insulating film 17a is selectively wet etched using an aqueous solution containing hydrochloric acid, thereby removing parts (i.e., ends) of the first gate insulating film 17a into which the fixed charge has been introduced such that the side surface of the first gate insulating film 17a is located at an inner side of the side surface of the first gate electrode 18a when viewed from above. To effectively remove the fixed charge, it is preferable to remove parts of the first gate insulating film 17a each extending to a distance of about 1 nm to about 2 nm from the original side surface thereof. In this process step, the use of the aqueous solution containing hydrochloric acid enables selective removal of the first gate insulating film 17a containing lanthanum. Thus, formation of a mask is unnecessary.

Then, as illustrated in FIG. 5C, a silicon nitride film is deposited by CVD on the semiconductor substrate 10 to a thickness of about 8 nm, and then is subjected to dry etching, thereby forming a first offset spacer 20a and a second offset spacer 20b. Subsequently, through lithography and ion implantation, arsenic is implanted in the first active region 10a with an implantation energy of, for example, 2 keV at an implantation dose of 1×10¹⁵/cm² with the first gate electrode 18a used as a mask, thereby forming an n-type first extension region 21a in a part of the first active region 10a at each side of the first gate electrode 18a. On the other hand, boron is implanted in the second active region 10b with an implantation energy of, for example, 2 keV at an implantation dose of 1×10¹⁵/cm² with the second gate electrode 18b used as a mask, thereby forming a p-type second extension region 21b in a part of the second active region 10b at each side of the second gate electrode 18b.

Subsequently, with a known method, a first sidewall spacer 22a is formed on each side surface of the first gate electrode 18a with the first offset spacer 20a interposed therebetween. Then, using the first gate electrode 18a and the first sidewall spacer 22a as masks, ion implantation of an n-type impurity is performed, thereby forming n-type first source/drain regions 23a in parts of the first active region 10a at both sides of the first gate electrode 18a. On the other hand, a second sidewall spacer 22b is formed on each side surface of the second gate electrode 18b with the second offset spacer 20b interposed therebetween. Then, using the second gate electrode 18b and the second sidewall spacer 22b as masks, ion implantation of a p-type impurity is performed, thereby forming p-type second source/drain regions 23b in parts of the second active region 10b at both sides of the second gate electrode 18b.

Then, thermal treatment at about 1050° C. is performed such that impurities implanted in the extension regions and the source/drain regions are diffused, thereby forming an NMIS transistor 101 and a PMIS transistor 102. At this time, the end of the first extension region 21a coincides with the end of the first gate insulating film 17a (i.e., the boundary between the first gate insulating film 17a and the first offset spacer 20a) or is at a position situated nearer the middle of the first gate electrode 18a in relation to the end of the first gate insulating film 17a (such that the first extension region 21a overlaps the end of the first gate insulating film 17a) when viewed from above.

Thereafter, with a known method, a silicide layer 27 containing a silicide material such as nickel is formed on the first gate electrode 18a, the second gate electrode 18b, the first source/drain regions 23a, and the second source/drain regions 23b, and then an interlayer insulating film 25, a contact 24, and an interconnect 26 are formed in this order.

With the method of this embodiment, the gate insulating film contains lanthanum and aluminium, thus reducing the threshold voltages of the NMIS transistor and the PMIS transistor. As a result, damage on the ends of the gate insulating film can be minimized.

In the foregoing description, the high-k material for the gate insulating film contains hafnium, as an example. However, the present disclosure is not limited to this example, and other high-k materials such as aluminium oxide, zirconium oxide, and tantalum oxide may be used in the same manner. Further, multiple ones of such high-k materials may be used such that a gate insulating film having a high dielectric constant is made of a compound high-k film containing a plurality of high-k materials.

In the foregoing description, titanium nitride is used for the metal material for forming the gate electrode, as an example. However, the present disclosure is not limited to this example. The gate electrode (i.e., the lower gate electrode) may be made of a metal film or a metal compound film containing tantalum, molybdenum, aluminium, carbon, nitrogen, or silicon, for example.

In the foregoing description, silicon nitride is used as a material for the offset spacers, as an example. However, the present disclosure is not limited to this example. An insulating material including boron, carbon, and silicon may be used as long as no negative fixed charge is introduced in the gate insulating film.

As described above, the present disclosure is useful for a method for forming a transistor having a low threshold voltage, for example.

What is claimed is:

1. A semiconductor device, comprising:
a substrate including a first active region and a second active region;
an NMIS transistor provided on the first active region; and
a PMIS transistor provided on the second active region, wherein
the NMIS transistor includes a first gate insulating film provided on the first active region and containing a high-k dielectric and a first gate electrode provided on the first gate insulating film and containing a metal material,
the PMIS transistor includes a second gate insulating film provided on the second active region and containing a high-k dielectric and a second gate electrode provided on the second gate insulating film and containing a metal material,
a side surface of the first gate insulating film is located at an inner side of a side surface of the first gate electrode, and
a ratio of a length of the first gate insulating film along a gate length direction to a length of the first gate electrode along the gate length direction is lower than a ratio of a length of the second gate insulating film along the gate length direction to a length of the second gate electrode along the gate length direction.

2. The semiconductor device of claim 1, wherein the NMIS transistor further includes an n-type first extension region formed in a part of the first active region located at each side of the first gate electrode,
the PMIS transistor further includes a p-type second extension region formed in a part of the second active region located at each side of the second gate electrode, and
an end of the first extension region coincides with an end of the first gate insulating film or is at a position situated nearer a middle of the first gate electrode in relation to the end of the first gate insulating film.

3. The semiconductor device of claim 2, wherein the NMIS transistor further includes a first offset spacer of silicon nitride provided on a side surface of the first gate electrode and a side surface of the first gate insulating film, and
the PMIS transistor further includes a second offset spacer of silicon nitride provided on a side surface of the second gate electrode and a side surface of the second gate insulating film.

4. The semiconductor device of claim 1, wherein the first gate insulating film contains lanthanum, and
the second gate insulating film contains aluminium.

5. The semiconductor device of claim 1, wherein the first gate electrode includes a first lower gate electrode provided on the first gate insulating film and made of a metal or a metal compound and a first upper gate electrode provided on the first lower gate electrode and made of polysilicon, and
the second gate electrode includes a second lower gate electrode provided on the second gate insulating film and made of a metal or a metal compound and a second upper gate electrode provided on the second lower gate electrode and made of polysilicon.

6. The semiconductor device of claim 1, wherein an end of the second gate insulating film is doped with a larger amount of fixed charge than an end of the first gate insulating film.

7. The semiconductor device of claim 1, wherein a side surface of the second gate insulating film is flush with a side surface of the second gate electrode.

8. The semiconductor device of claim 1, wherein a side surface of the second gate insulating film is located at an inner side of a side surface of the second gate electrode.

9. The semiconductor device of claim 1, wherein an end of the second gate insulating film projects from a side surface of the second gate electrode.

10. The semiconductor device of claim 1, wherein the high-k dielectric has a relative dielectric constant higher than that of Si₃N₄.

11. The semiconductor device of claim 1, wherein the first gate insulating film includes a first lower gate insulating film provided on the first active region and a first upper gate insulating film provided on the first lower gate insulating film and made of the high-k dielectric, and
the second gate insulating film includes a second lower gate insulating film provided on the second active region and a second upper gate insulating film provided on the second lower gate insulating film and made of the high-k dielectric.

12. The semiconductor device of claim 11, wherein the first lower gate insulating film and the second lower gate insulating film are made of a first dielectric film of silicon oxide, and
the first upper gate insulating film and the second upper gate insulating film are made of a second dielectric film of a high-k material containing hafnium.

13. The semiconductor device of claim 1, wherein the metal material is made of titanium nitride.

14. The semiconductor device of claim 1, wherein the metal material is made of one of a metal film or a metal compound film, and
each of the metal film and the metal compound film contains at least a material selected from the group consisting of tantalum, molybdenum, aluminium, carbon, nitrogen, and silicon.

15. The semiconductor device of claim 1, further comprising:
a first offset spacer provided on a side surface of the first gate electrode; and
a second offset spacer provided on a side surface of the second gate electrode, wherein
a part of the first offset spacer is located under an end of the first gate electrode, and
the second offset spacer is not located under an end of the second gate electrode.
